(19) United States
(12) Patent Application Publication
(10) Pub. No.: US 2022/0292429 A1
(43) Pub. Date: Sep. 15, 2022

(54) METHOD AND SYSTEM FOR MONITORING A COTTON CROP

(71) Applicant: Cotton Seed Distributors Ltd, Wee Waa (AU)

(72) Inventors: James QUINN, Wee Waa (AU); Chris TEAGUE, Goondiwind (AU)

(21) Appl. No.: 17/349,261

(22) Filed: Jun. 16, 2021

(30) Foreign Application Priority Data
Mar. 9, 2021 (AU) 2021900656

(51) Int. Cl. G06Q 10/06; G06Q 50/02; A01B 79/00; A01C 21/00

(52) U.S. Cl. CPC G06Q 10/06393; G06Q 50/02; A01B 79/005; A01C 21/005

(57) ABSTRACT

A machine-implemented method of monitoring a cotton crop. The method comprising collecting cotton growing data from a plurality of cotton growers and storing same in a database stored in at least one computer. Passing the cotton growing data as simulation parameters to a crop model stored in the at least one computer or another computer connected thereto, in which at least some of the cotton growing data are variables treated as representative crop profiles. Simulating events for the cotton crop based on the cotton growing data. At least some key establishment variables of the cotton crop are initially provided to the crop model for initially estimating a simulated profile of the cotton crop that include an estimated end of season yield of the cotton crop. Then monitoring the cotton crop at key growth stages such that data can be entered to record an actual profile of the cotton crop and enable re-estimation of the end of season yield of the first cotton crop based on a combination of actual data and simulated profile data.

### TECHNICAL FIELD

This invention relates to a machine implemented method and system for monitoring of a cotton crop. In particular, the present invention is described with reference to monitoring the cotton crop where initially an end of season yield is estimated using a simulation model, and then re-estimated at key growth stages based on data collected whilst the crop is in progress. More particularly, the present invention is described with reference to benchmarking of the cotton crop with previous crops, or another similar cotton crop also being simultaneously monitored.

### BACKGROUND

Up until about fifteen years ago it was difficult for a cotton grower to monitor their cotton crop. It was possible for a grower to record data regarding the crop whilst it was in progress, but it was difficult for the grower to use that data for the purposes of making management decisions. In Australia, The Cotton Research and Development Corporation together with the Commonwealth Scientific and Industrial Research Organisation developed a group of web-based tools known as “CottAssist” in the period 2008 to 2014, which delivered cotton research and up to date information to assist growers and consultants with cotton crop management decisions. CottAssist allowed for details of a proposed cotton crop, including commencement date to be entered into a monitoring program, and by recording data for the cotton crop certain attributes could be monitored or assessed. For instance, CottAssist gave a user access to a Day Degree Report which relied on a Day Degree calculation used by the Australian cotton industry to indicate the amount of crop development expected for a given day. CottAssist also provided the user with season climate analysis, aphid yield loss, diapause/emergence (Heliothis Pupae induction and moth emergence predictor), and estimating last effective flower based on frost date or defoliation date using historical data. It also estimated Micronaire (indirect measurement of fibre maturity and fineness) relying on old cotton varieties, mite yield loss (pest estimation), and allowed for monitoring the nutrient status and water quality of the cotton crop.

Because there are many important variables in cotton growing, such as the region where the cotton crop is grown, the cotton seed variety, system type, and commencement date, the CottAssist tools could not be used for estimating a key growth stage such as “first flower” or estimating a yield for a particular crop, or for any form of benchmarking the crop.

The present invention seeks to ameliorate at least some of the problems and shortcoming associated with the prior art.

### SUMMARY OF INVENTION

In a first aspect the present invention consists of a machine-implemented method of monitoring a cotton crop, said method comprising:

collecting cotton growing data from a plurality of cotton growers and storing same in a database stored in at least one computer;
passing said cotton growing data as simulation parameters to a crop model stored in said at least one computer or another computer connected thereto, in which at least some of the cotton growing data are variables treated as representative crop profiles; and simulating events for said cotton crop based on said cotton growing data, and
wherein at least some key establishment variables of said cotton crop are initially provided to said crop model for initially estimating a simulated profile of said cotton crop that include an estimated end of season yield of said cotton crop, then monitoring said first cotton crop at key growth stages such that data can be entered to record an actual profile of said cotton crop and enable re-estimation of the end of season yield of said first cotton crop based on a combination of actual profile data and simulated profile data.

Preferably at least one of said key growth stages is First Flower of said cotton crop and said re-estimation of the end of season yield can occur with data collected at said First Flower or thereafter.

Preferably the data collected at said First Flower includes the date of said First Flower.

Preferably when said First Flower of said cotton crop is reached and said cotton crop data of said First Flower is entered into said crop model, the actual profile of said cotton crop as it progresses, can be benchmarked with the profile of another crop.

Preferably in one embodiment said another crop is an earlier crop identified by a historical profile stored in said database.

Preferably in another embodiment said another crop is a similar crop for which data is being collected for and said similar crop has also reached its First Flower and said crop and said similar crop are comparatively benchmarked to each other.

Preferably attributes of said simulated profile can be displayed graphically, and when data is entered to record an actual profile of said cotton crop, attributes of said actual profile and simulated profile are graphically represented together for comparison to each other.

Preferably attributes of said cotton crop and said another crop can be graphically represented together for comparison to each other.

Preferably said simulated profile includes a Simulated Time To Effective First Flowering (STEFF) estimation.

In a second aspect the present invention consists of a system for monitoring a cotton crop on a web-based network, said system comprising:

(i) at least one computer operated on behalf of a simulation agent for the purpose of administering a web based crop simulation model using associated simulation software and a database for storing cotton growing data in the form of variables treated as representative crop profiles, said web-based network comprising a website;
(ii) at least a second computer used by a first user to access said crop simulation model via an online account, and said website having a user web page associated with said first user;
wherein said user web page is provided with a link to said simulation software so that instructions may be provided to simulate at least one simulated profile based on at least some key establishment variables of said cotton crop, said simulated profile including an estimated end of season yield of said cotton crop; and
wherein during monitoring said cotton crop at key growth stages data can be entered by said user to record an actual profile of said cotton crop and enable re-estimation of the end of season yield of said first cotton crop based on a combination of actual profile data and simulated profile data.

Preferably at least one key growth stage is First Flower of said cotton crop and said re-estimation of the end of season yield can occur with data collected at said First Flower or thereafter.

Preferably the data collected at said First Flower includes the date of said First Flower.

Preferably when said First Flower of said cotton crop is reached and said cotton crop data of said First Flower is entered into said crop model, the actual profile of said cotton crop as it progresses, can be benchmarked with the profile of another crop.

Preferably in one embodiment said another crop is an earlier crop identified by a historical profile stored in said database.

Preferably said another crop is a similar crop for which data is being collected for and said similar crop has also reached its First Flower and said crop and said similar crop are comparatively benchmarked to each other.

Preferably attributes of said simulated profile can be displayed graphically, and when data is entered to record an actual profile of said cotton crop, attributes of said actual profile and simulated profile are graphically represented together for comparison to each other.

Preferably attributes of said cotton crop and said another crop can be graphically represented together for comparison to each other.

Preferably said simulated profile includes a Simulated Time To Effective First Flowering (STEFF) estimation.

In a third aspect the present invention consists of a machine implemented method for benchmarking a cotton crop, said method comprising:

storing cotton growing data from a plurality of cotton growers in at least one computer; passing said cotton growing data as simulation parameters to a crop model stored in said at least one computer or another computer connected thereto, in which at least some of the cotton growing data are variables treated as representative crop profiles; and simulating events for said cotton crop based on said cotton growing data, and
wherein at least some key establishment variables of said cotton crop are initially provided to said crop model for initially estimating a simulated profile of said cotton crop that include an estimated end of season yield of said cotton crop, then monitoring said first cotton crop at key growth stages such that data can be entered to record an actual profile of said cotton crop and enable re-estimation of the end of season yield of said first cotton crop based on a combination of actual profile data and simulated profile data, and at least one of said key growth stages is First Flower of said cotton crop and said re-estimation of the end of season yield can occur with data collected at said First Flower or thereafter, and when said First Flower of said cotton crop is reached and said cotton crop data of said First Flower is entered into said crop model, the actual profile of said cotton crop as it progresses, can be benchmarked with the profile of another crop.

Preferably said another crop is either an earlier crop identified by a historical profile stored in said database, or a similar crop for which data is being collected for and said similar crop has also reached its First Flower and said cotton crop and said similar crop are comparatively benchmarked to each other.

### BRIEF DESCRIPTION OF DRAWINGS

FIG. 1 is a diagrammatic view of a system for simulating, monitoring, and benchmarking a cotton crop over a web-based network.

FIG. 2 is a flow diagram of simulating and monitoring a cotton crop using the system of FIG. 1.

FIG. 3 is a summary table of data inputted and simulated for an example crop being monitored using the system shown in FIG. 1.

FIG. 4(a) is a graph plotting Node Production against Day Degrees, and NAWF against Day Degrees, for the example crop shown in FIG. 3.

FIG. 4(b) is a graph plotting Bolls/m against Day Degrees, and Plant height against Day Degrees, for the example crop shown in FIG. 3.

### BEST MODE OF CARRYING OUT THE INVENTION

### Overview of Cotton Crop Variables and Recording of Data

Prior to describing the embodiment of the present invention, the following should be noted.

A cotton crop at its outset can be defined by certain key establishment variables, such as:
The “Region”, namely the geographic location of the proposed cotton crop;
The “Cotton Seed Variety”;
“System Type”, namely Irrigated or Dryland; and
“Seed Imbibed Date”, namely the date of first uptake of water by the cotton seed.

Whilst hundreds of cotton seed varieties are commercially available, each cotton seed variety has its own attributes. These attributes include suitability for “System type”, namely Irrigated or Dryland, and in some instances the variety is suited for both Irrigated and Dryland systems. Other attributes include but are not limited to seed density, growth habit, boll size, pest resistance and certain measures of fibre quality. Usually, a cotton seed variety is chosen to suit conditions and system types for a particular growing region and the technology employed.

For any cotton crop, after initially recording details of the “abovementioned key establishment variables” it is possible to record data at regular intervals during the growth of the crop, including at the key growth stages of:
First Flower;
Cut-out;
Flowering Progression; and
End of Season.

### A Method and System Embodiment for Monitoring a Cotton Crop

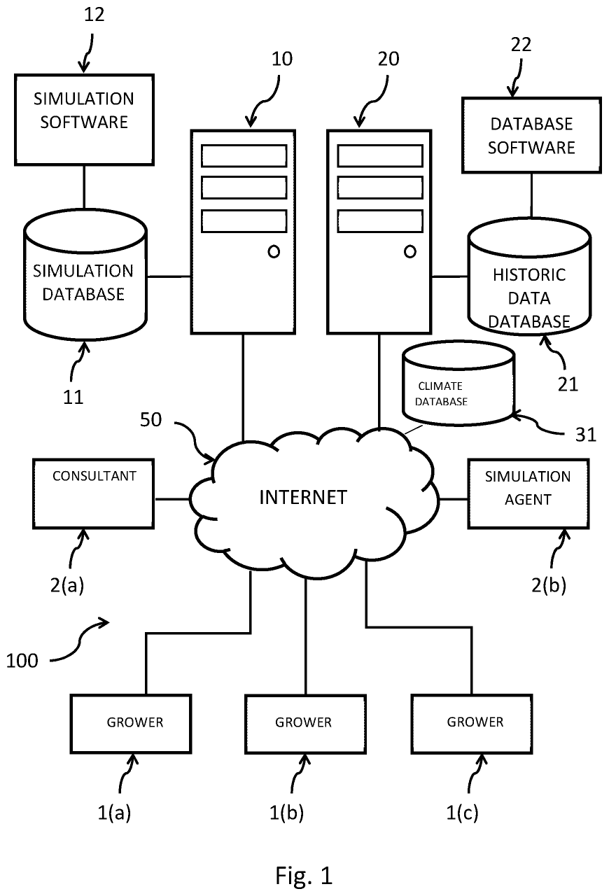

FIG. 1 depicts a first embodiment of a system 100, which allows for users on a web-based network over the Internet 50 to simulate a “cotton crop” making an estimation regarding the potential yield of the crop. Once the cotton crop is planted, system 100 allows users to monitor its growth so that estimation regarding the potential yield of the crop can be re-estimated and benchmarked to previous crops and/or to “similar” crops also being monitored via system 100.

For the purposes of system 100, a database 21 is established that contains agronomic data of past cotton crops, referred to here as “historical profiles”. Each historical profile includes the key establishment variables of a particular past crop, as well data recorded during the key growth stages of that past cotton crop, as well the actual yield. Preferably, database 21 should have built up various “historical profiles” dating back at least five years for a particular growing region and cotton seed variety. At least some of the cotton growing data from these historical profiles are variables treated as representative crop profiles.

A plurality of users, five of which are shown in FIG. 1 (shown with computer access) are users of a “web-based simulation and monitoring network”. These five users are cotton growers 1(a)-1(c), consultant 2(a), and simulation/monitoring agent 2(b). Cotton Growers 1(a) -1(c) may be the actual cotton grower, or an employee or sub-contractor of the cotton grower, such as a farm manager. The “web-based simulation and monitoring network” is administered by simulation agent 2(b) (or its website administrator), via at least a first computer 10.

A simulation database 11 associated with simulation software (application) 12 reside on first computer 10 administered by simulation agent 2(b).

The simulation database 11 associated with simulation software 12 may also preferably be operably communicating with one or more third-party databases. One example of a third-party database 31, may be a climate database containing climate data. An example of a climate database is the “SILO climate database” managed by the Queensland Government, containing continuous daily climate data for Australia from 1889 to the present, in a number of ready to use formats.

The users access software (application) 12, via a website. A website page screen selection (not shown) allows users 1(a)-1(c) to register and then use the web-based simulation network by selecting various menus. Each user 1(a)-1(c) and 2(a), registers their details with the system in a conventional manner. Alternatively, the simulation agent 2(b) may establish an account for any user 1(a)-1(c) and 2(a), and send an invite to that user via email, to activate the account. The account allows the users1(a)-1(c) and 2(a) to monitor and benchmark at least one crop.

Database 21, which contains the “historical profiles”, namely data of past cotton crops, with associated database software 22 resides on another computer 20 and is also administered by the earlier mentioned administrator. Database 21 contains a relational database of the historical profiles.

In this embodiment, the “historical profiles” will preferably have certain attributes of past cotton crops. These attributes include the “key attributes” known at establishment, namely the Region of past crop, Cotton Seed Variety, System Type (Irrigated or Dryland), and Seed Imbibed date. In addition to the key attributes, the historical profiles will have recorded data such as “date of first flower” “Cut-out” (date when the plant has 4-5 “nodes above white flower’ or NAWF), Day degrees data, plant height at periodic intervals, and the actual yield of crop.

A cotton grower 1(a) may at the outset before planting a proposed crop, input the four key attributes into software 12, namely the Region, Cotton Seed Variety, System Type and “proposed” Seed Imbibed Date. The simulation software 12 using the “historical profiles” will estimate a proposed “simulated profile” for the crop to be monitored, which includes the Simulated Time To Effective First Flowering (STEFF), provides a Day Degrees Report and a “yield estimate”. The simulation software 12 may do this estimation, namely generate a “simulated profile” via look-up tables from database 21 and from climate data base 31 and use interpolation and/or extrapolation to estimate STEFF and yield. As such, simulation software 12 is useful to grower 1 (a) to get some initial estimates STEFF and yield, based on proposed key attributes.

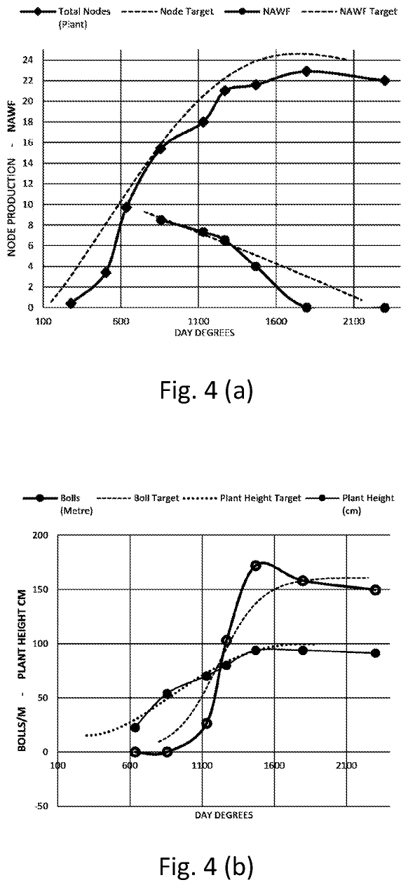

When cotton grower 1(a) plants the cotton crop, namely the actual cotton crop to be monitored, the key attributes including the “actual” Seed Imbibed Date can then be inputted at outset via simulation software 12 to provide a “simulated profile” that includes estimates such as STEFF and yield (bales per hectare). This simulation can also provide simulated targets for Total nodes (plant), NAWF and Plant height at certain dates growth stages. These targets can be used to generate graph representations of target crop performance as shown in FIGS. 4(a) and 4(b) that can be viewed by the user. These graphs will be discussed later with reference to an example.

Once the “actual cotton crop” has been planted, grower 1 (a) monitors the crop, or a third party may monitor the crop on behalf of grower 1(a). This third party may be a cotton crop monitoring expert, which may for instance be consultant 2(a). Grower 1(a) or a consultant 2(a) authorised to monitor the actual crop, may input observed data for the actual crop into a record for the crop being monitored. For example, a key observation is when actual “First Flower” occurs, which is one the four earlier mentioned key growth stages of a cotton crop. This data being recorded can be considered the data making up the “actual profile” for the cotton crop being monitored.

The measurement and recording of observed data will be in accordance with guidelines approved by simulation agent 2(b).

Once the date of “actual First Flower” is entered for the cotton crop being monitored, the simulation software 12 can re-estimate the yield estimate (bales per hectare) using the “actual First Flower” date. This in effect allows for a refinement of the earlier yield estimate, which initially was calculated on historical profiles alone. Should there be a significant discrepancy between the refined yield estimate based on the “actual First Flower” date of the cotton crop, and the original simulated yield estimate predicted, particularly if the refined yield estimate is significantly lower (i.e. the cotton crop appears to be under-performing), then grower 1(a) and/or consultant 2(a) can analyse data and make management decisions. For example, the day degree report for the actual crop being monitored and recorded may sufficiently differ to that of the historical profiles of previous years, thus showing a significant difference between the simulated yield estimate at outset, to that refined yield estimate based on “actual First Flower” date.

At each of the other key growth stages that occur after actual First Flower, such as “Cut-out”, “Flowering Progression” and “End of Season”, it is possible to recalculate and further refine the yield estimate (bales per hectare) using simulation software 12. Again, just like after the “actual First Flower” date is recorded, the yield estimate can be recalculated at any of these stages based on recorded data, to further refine the yield estimate, and to subsequently analyse the data and make management decisions for the crop being monitored.

Once the first key growth stage of “actual First Flower” has been reached and the data recorded for the crop being monitored, the progress of the crop can be also benchmarked. The benchmarking of the present crop can be against a past crop, namely a crop identified by a historical profile in database 21, or alternatively a similar crop also being monitored via system 100 by another user (grower) 1(b).

To benchmark the crop being monitored, the crop must have at least reached the actual First Flower date, and it can then be benchmarked against an earlier historical profile. For example, an earlier historical profile being used for bench marking purposes, may be a past crop of the same grower 1(a) or of another grower 1(b), having the same key attributes of Region of past crop, Cotton Seed Variety, System Type (Irrigated or Dryland), and similar Seed Imbibed Date.

Grower 1(a) may also choose to “real-time” comparative benchmark his crop being monitored, against another grower's crop also being monitored in the same region. For example, both of growers 1(a) and 1(c) may presently be growing crops in the same region, with the same Cotton Seed Variety, System Type (Irrigated or Dryland), and similar Seed Imbibed Date. To benchmark against each other in real-time, growers 1(a) and 1(c), which are both registered users of the “web-based simulation and monitoring network” administered by the earlier mentioned administrator, have via system 100 authorised each other “read only” access to the record (actual profile) for each other's crops being monitored. Once both these crops have reached actual first flower, the recorded data for each other's crops can be compared during the various stages.

For the purposes of simulation, monitoring, estimation, and benchmarking, it should be understood, that certain key attributes may not necessarily be exactly the same. For example, the cotton crop that grower 1(a) intends to monitor may be in the same Region, have the same Cotton Seed Variety, and System Type (Irrigated or Dryland) as certain historical profiles in database 21, however the Seed Imbibed Date in past years may not be identical to the calendar day of the month, when compared to the present cotton crop to be monitored and benchmarked. However, for the purpose of the present embodiment a Seed Imbibed Date of a “historical profile” will be considered to be a “similar date” to that of the crop to be monitored when it falls within ten calendar days on either side of that date (day of the month). So, for example a Seed Imbibed Date of the 7 Aug. 2019 for a historical profile, would be considered a “similar date” say to a proposed crop to be planted on 15 Aug. 2021, because the “7^{th} August” is within ten calendar days of the 15^{th} August.

Also, for the purposes of real-time benchmarking a cotton crop being monitored by grower 1(a), against that of another crop grown by grower 1(c) will not necessarily have the same “Seed Imbibed Date”. However, if the seed imbibed date of the grower's crop 1(a) is within ten calendar days of the other crop being grown by grower 1(c), then for the purpose of the present embodiment they should be considered crops having a “similar Seed Imbibed Date”, for the purposes of real-time benchmarking.

Newly planted crops for known cotton varieties being monitored by growers 1(a) to 1(c) via system 100, will once completed to harvest, and the actual yield recorded, will with the authorisation of simulation agent 2(b) be added to the existing historical profiles in database 21, thus adding to the accessible historical profiles accessed by simulation software 12 to monitor and benchmark future cotton crops.

The historical profiles contained within database 21 initially contain details of past crops that have used well known cotton seed varieties for a particular region. As such, when planting new cotton crops, simulation software 12 will be able to readily identify historical profiles that used known cotton seed varieties in a particular region, for the purposes of simulating and estimating yields for a proposed or recently planted cotton crop in that same region.

New cotton seed varieties are being developed on a regular basis, and whilst there are hundreds of known cotton varieties, many newly developed cotton seed varieties, are closely related to earlier varieties and the differences between them are in many instances small differences. As such many cotton seed varieties are categorized into families, for identification purposes, due to their closely related attributes. When new cotton seed varieties are developed, data regarding the new cotton seed variety may be entered by simulation agent 2(b) into database 21, including details to associate same with the most closely related known cotton seed varieties (earlier family members) for which historical profiles already exist in database 21. Should grower 1(a) be planting a crop using a new cotton seed variety, for which no historical profile exists, simulation software 12 may carry out its estimation via look-up tables from database 21 based on historical profiles of one or more closely related seed varieties and use interpolation and/or extrapolation to estimate STEFF and yield estimates. In such instance, once the actual first flower date is recorded, simulation software 12 will be re-estimating the yield estimate using the “actual first flower” date of the new cotton variety and the existing data from historical profiles of the associated (related) seed varieties.

Over time, as a number of historical profiles are recorded for a relatively new cotton variety used in a particular region, simulation software 12 may initially rely on a combination of historical data for the exact cotton seed variety and one or more closely related varieties. However, once a certain number of historical profiles exist for a particular cotton seed variety going back a number of years, say for example five years, any future simulation to be carried out by simulation software 12, may occur on the historical profiles of that cotton seed variety alone.

As such, not only does system 100 allow for monitoring, estimation, and benchmarking of a cotton crop for a grower, it also allows for database 21 to have additional historical profiles added thereto by participation by the growers.

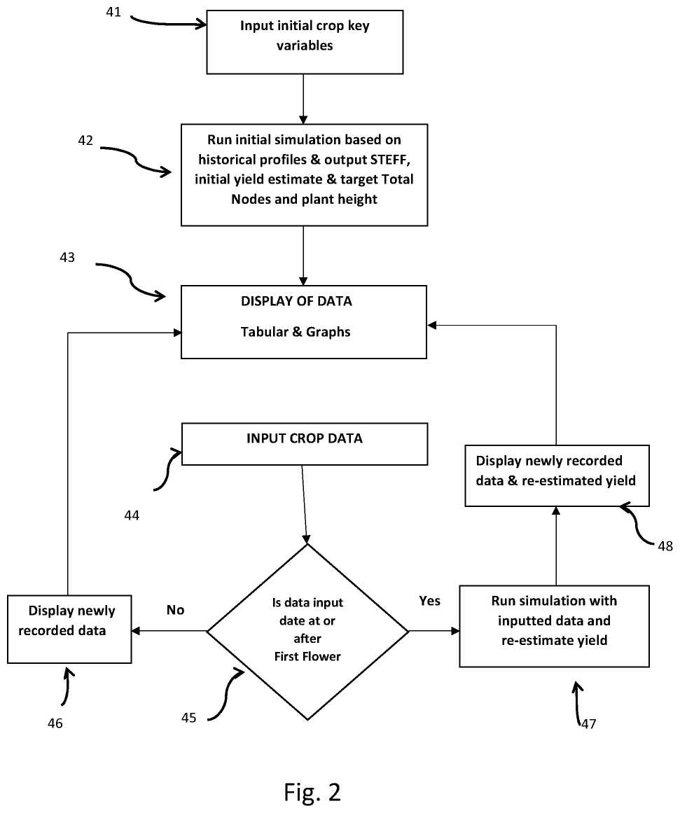

With reference to FIG. 2, a grower 1(a), may for instance
initially input the four key establishment variables for a newly planted cotton crop as indicated by block 41;
the initial simulation carried out by simulation software 12 based on historical profiles takes place and STEFF, initial yield estimate, and target Total nodes and target plant height are estimated as indicated at block 42;
these targets and estimates are then displayed in “Display of Data” as indicated by block 43.
At periodic intervals, data that has been recorded for the cotton crop are inputted into the simulation software 12 as indicated at block 44;
When such data has been inputted, the user will be asked to confirm the stage of assessment, and if the data input date is not after the First Flower date as indicated at block 45, then only the newly inputted data is displayed, see blocks 46 and 43.
If, however as indicated at blocks 45 and 47 the data input is at or after First Flower, the simulation will be re-run with the inputted data and the predicted yield (bales/hectare) will be re-estimated.
Following re-estimating of yield as indicated at block 47, the newly recorded data and re-estimated yield will be displayed as indicated at blocks 48 and 43.

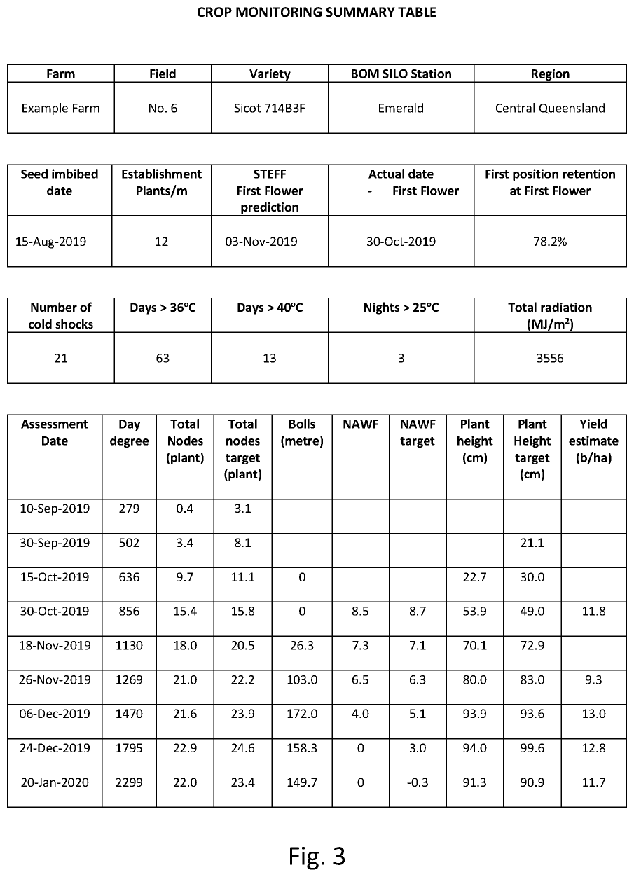

An example of monitoring a cotton crop will now be described with reference to FIGS. 3 and FIGS. 4(a) and 4(b), to describe the use of the earlier described embodiment.

### EXAMPLE

The example cotton crop had the following four key establishment variables.
Region: Central Queensland, Australia
Cotton Seed Variety: Sicot 714B3F
System Type: Irrigated
Seed Imbibed Date: 15 Aug. 2019

Other details regarding the crop are shown in FIG. 3.

Because the region is Central Queensland, the simulation software 12 accessed historic climatic data from database 31, relying on data recorded by Australian Government Bureau of Meteorology (BOM) SILO station located in Emerald, Queensland.

At outset, the abovementioned four key establishment variables were entered into the record for the crop held in simulation database 11. Simulation software 12 in combination with historical profiles from database 21 and climatic data from database 31, uses this information to generate a “simulated profile” that includes initial yield estimate (prediction) of 8.7 bales/hectare along with a predicted STEFF date of 3 Nov. 2019. The abovementioned initial yield estimate of 8.7 bales/hectare is not shown in FIG. 3.

Along with these estimates of yield and STEFF, simulation software 12 estimates over the duration of the crop, Total nodes target (plant), NAWF target, and Plant height target. These targets for total nodes, NAWF and plant height are shown in various columns of the lower table in FIG. 3.

FIG. 4(a) depicts a graph showing Node Production/Day Degrees and NAWF/Day Degree curve relationships. In both instances the “target” Node production/Day Degrees and “target” NAWF/Day Degrees curves are plotted as dotted lines.

FIG. 4(b) depicts a graph showing Bolls per metre/Day Degrees and Plant height/Day Degree curve relationships. In both instances the “target” Bolls per metre/Day Degrees and “target” Plant height/Day Degrees curves are plotted with dotted lines.

In use, these graphs depicted in FIGS. 4(a) and 4(b) are presented to grower 1a and/or a consultant 2a, both users of the web-based simulation software 12 of system 100, who are authorised to view crop monitoring data. These graphs initially only depict the “target” curves (as dotted lines) based on the key establishment variables relied upon by simulation software 12. As data is recorded over the duration of the crop, solid line representations of the “actual” curve relationships then appear and are updated during the crop cycle. This means that attributes of both the “simulated profile”, namely the target profile, and the actual profile are presented together in graph form for comparison purposes.

During the initial eight weeks of this example crop, data was recorded for Total nodes and plant height, along with Day Degree on three “Assessment dates” 10 Sep. 2019, 30 Sep. 2018, and 15 Oct. 2019. For the latter date, plant height was also recorded.

As you can see in this example, some of the “actual data” is recorded and appears on the curve from the first assessment date (10 Sep. 2019), such as Total Nodes (Node production) shown in FIG. 4(a), whilst others such Bolls/m and plant height (cm) do not get recorded and appear on their curve shown on FIG. 4(b) until the third assessment date (15 Oct. 2019).

The actual date of First Flower is at the fourth assessment date of 30 Oct. 2019, which occurs slightly earlier than the STEFF date of 3 Nov. 2019 estimated by the simulation software 12.

Based on the recorded data (actual profile) up to and including the actual First Flower date, the simulation software 12 was then used to recalculate the “yield estimate” based on a combination of recorded data and Day Degree data for the crop being monitored and the originally relied upon historical profiles in database 21. This recalculated yield estimate has significantly been re-estimated to an increased amount of 11.8 bales/hectare.

For a user observing the data for the monitored cotton crop, and particularly during the early weeks of the monitored crop, the data shows that the recorded “Total nodes” and recorded “Plant height” are well behind the target estimations (predictions). Cold weather at emergence and through establishment of this crop was well behind what was predicted on the boll target curve at First Flower (30 Oct. 2019), see FIG. 4(b).

A grower and/or a consultant monitoring the crop, could by using a Day Degree Calculator identify that for the first thirty-two days, twenty of those days had read as “cold shock” days with an average temperature of 19.5° C. for this period. Thus, by looking at the Day Degree Calculator the user and/or consultant had an explanation as to why there was delay in the growth of this cotton crop in the initial stage, that is reflected in the early recorded data for “Total nodes and “Plant height” against the respective simulated targets.

By the “Cut-out” date, namely the assessment date of 6 Dec. 2019, the crop had recovered well from the cold start to set 172 bolls/m, which by looking at FIG. 4(b), is well above the boll target curve. When simulation software 12 is used to recalculate the “yield estimate” based on recorded data up to and including Cut-out, the yield estimate is now estimated at 13.0 bales/hectare.

A flowering progression assessment was carried out on 24 Dec. 2019, and you can see there was a drop in boll numbers to 158.3 bolls/m. To a grower and/or consultant looking at this data, they could explain this shedding (reduction in bolls/m) due to environmental impact, namely excessive high temperatures, on the plants during this period of boll fill. When simulation software 12 is used to recalculate the “yield estimate” based on recorded data up to and including the data recorded on 24 Dec. 2019, the yield estimate is now estimated at 12.8 bales/hectare, which is slightly lower than what was estimated at the previous assessment date.

The End of Season data, namely the data recorded on the last assessment date, was carried out on 20 Jan. 2020. Boll numbers have fallen to 149.7 bolls/m, back below the “target” bolls/m/Day Degree curve, see FIG. 4(b). The period from Cut-out (6 Dec. 2019) to End of Season (20 Jan. 2020) had some extreme weather, with thirty-eight days above 36° C. and ten days above 40° C. Added to these high temperatures, the crop experienced extreme canopy humidity, which are all contributing factors to boll shedding, while the plants were at peak demand to finish off the remaining bolls. When simulation software 12 is used to recalculate the “yield estimate” based on recorded data up to and including the data recorded on 20 Jan. 2020, the yield estimate is now estimated at 11.7 bales/hectare at picking.

Whilst the end of season modelling estimate was 11.7 bales/hectare, at picking the crop achieved an actual yield of 11.79 bales/hectare, which is a 99% accuracy on that simulated end of season estimate.

This abovementioned example demonstrates that re-estimation of yield, taken at key growth stages, and in particular at actual First Flower, is of benefit to the grower and consultants for the purposes of monitoring a cotton crop.

What should be understood is that for benchmarking purposes the crop described could have been historically benchmarked against a particular “historical profile” accessible from simulation database 21 during its progress. Just like that shown in FIGS. 4(a) and 4(b) where the actual crop curve is being shown relative to a target curve, you could provide the curves of the historical profile so the actual crop being monitored can be benchmarked relative to a particular historical profile.

What should be understood is that any one historical profile having the same four key establishment variables may be for a crop that had a significantly different set of climatic conditions. In the abovementioned Example, the crop was slow to start due to colder than usual days at the outset, and then suffered extreme heat between Cut-out and End of Season, so the benchmarking against any one historical profile, may not necessarily be as useful if similar climatic conditions were not approximately the same.

As climatic conditions play a significant role in crop performance, the crop shown in the abovementioned Example would benefit from “comparative benchmarking” against a similar crop, namely planted in the same region of Central Queensland, seed variety Sicot 714B3F, irrigated and having a similar Seed Imbibed Date, namely within ten days of the Seed Imbibed Date. If the grower of the Example crop was grower 1(a) and the grower of the similar crop was grower 1(c), and they gave “read only” access to each other's data, then the comparative benchmarking would be of benefit to both growers. Both the abovementioned Example crop and the similar crop being comparatively benchmarked would both be experiencing the relatively same climatic conditions, namely in this instance a slow start to the crop due to unusually colder weather, and extreme heat towards the end. As such, because both crops are experiencing similar climatic conditions, if there are significant differences of the crops as they progress, namely one crop appears to be underperforming relative to the other comparative benchmarked crop, then the grower (or consultant) can assess factors, other than climatic conditions that may be affecting the crop performance. This will allow the grower and/or consultant to consider the causes and make the necessary management decisions to address the under-performance.

In the abovementioned system 100, it should be understood, that the “computer” used by users 1(a)-1(c) and 2(a) and 2(b) may be any computing device able to access the website by internet access, and may include, home or office computers, laptops, notebooks, tablets or smartphones.

The terms “comprising” and “including” (and their grammatical variations) as used herein are used in an inclusive sense and not in the exclusive sense of “consisting only of”.

1. A machine-implemented method of monitoring a cotton crop, said method comprising:
collecting cotton growing data from a plurality of cotton growers and storing same in a database stored in at least one computer;
passing said cotton growing data as simulation parameters to a crop model stored in said at least one computer or another computer connected thereto, in which at least some of the cotton growing data are variables treated as representative crop profiles; and simulating events for said cotton crop based on said cotton growing data, and
wherein at least some key establishment variables of said cotton crop are initially provided to said crop model for initially estimating a simulated profile of said cotton crop that include an estimated end of season yield of said cotton crop, then monitoring said first cotton crop at key growth stages such that data can be entered to record an actual profile of said cotton crop and enable re-estimation of the end of season yield of said first cotton crop based on a combination of actual profile data and simulated profile data.

2. A machine implemented method as claimed in claim 1, wherein at least one of said key growth stages is First Flower of said cotton crop and said re-estimation of the end of season yield can occur with data collected at said First Flower or thereafter.

3. A machine implemented method as claimed in claim 2, wherein the data collected at said First Flower includes the date of said First Flower.

4. A machine implemented method as claimed in claim 2, wherein when said First Flower of said cotton crop is reached and said cotton crop data of said First Flower is entered into said crop model, the actual profile of said cotton crop as it progresses, can be benchmarked with the profile of another crop.

5. A machine implemented method as claimed in claim 4, wherein said another crop is an earlier crop identified by a historical profile stored in said database.

6. A machine implemented method as claimed in claim 4, wherein said another crop is a similar crop for which data is being collected for and said similar crop has also reached its First Flower and said crop and said similar crop are comparatively benchmarked to each other.

7. A machine implemented method as claimed in claim 1, wherein attributes of said simulated profile can be displayed graphically, and when data is entered to record an actual profile of said cotton crop, attributes of said actual profile and simulated profile are graphically represented together for comparison to each other.

8. A machine implemented method as claimed in claim 4, wherein attributes of said cotton crop and said another crop can be graphically represented together for comparison to each other.

9. A machine implemented method as claimed in claim 1, wherein said simulated profile includes a STEFF estimation.

10. A system for monitoring a cotton crop on a web-based network, said system comprising:
(i) at least one computer operated on behalf of a simulation agent for the purpose of administering a web based crop simulation model using associated simulation software and a database for storing cotton growing data in the form of variables treated as representative crop profiles, said web-based network comprising a website;
(ii) at least a second computer used by a first user to access said crop simulation model via an online account, and said website having a user web page associated with said first user;
wherein said user web page is provided with a link to said simulation software so that instructions may be provided to simulate at least one simulated profile based on at least some key establishment variables of said cotton crop, said simulated profile including an estimated end of season yield of said cotton crop; and
wherein during monitoring said cotton crop at key growth stages data can be entered by said user to record an actual profile of said cotton crop and enable re-estimation of the end of season yield of said first cotton crop based on a combination of actual profile data and simulated profile data.

11. A system as claimed in claim 10, wherein at least one key growth stage is First Flower of said cotton crop and said re-estimation of the end of season yield can occur with data collected at said First Flower or thereafter.

12. A system as claimed in claim 11, wherein the data collected at said First Flower includes the date of said First Flower.

13. A system as claimed in claim 11, wherein when said First Flower of said cotton crop is reached and said cotton crop data of said First Flower is entered into said crop model, the actual profile of said cotton crop as it progresses, can be benchmarked with the profile of another crop.

14. A system as claimed in claim 13, wherein said another crop is an earlier crop identified by a historical profile stored in said database.

15. A system as claimed in claim 13, wherein said another crop is a similar crop for which data is being collected for and said similar crop has also reached its First Flower and said crop and said similar crop are comparatively benchmarked to each other.

16. A system as claimed in claim 10, wherein attributes of said simulated profile can be displayed graphically, and when data is entered to record an actual profile of said cotton crop, attributes of said actual profile and simulated profile are graphically represented together for comparison to each other.

17. A system as claimed in claim 13, wherein attributes of said cotton crop and said another crop can be graphically represented together for comparison to each other.

18. A system as claimed in claim 10, wherein said simulated profile includes a STEFF estimation.

19. A machine implemented method for benchmarking a cotton crop, said method comprising:
storing cotton growing data from a plurality of cotton growers in at least one computer;
passing said cotton growing data as simulation parameters to a crop model stored in said at least one computer or another computer connected thereto, in which at least some of the cotton growing data are variables treated as representative crop profiles; and simulating events for said cotton crop based on said cotton growing data, and
wherein at least some key establishment variables of said cotton crop are initially provided to said crop model for initially estimating a simulated profile of said cotton crop that include an estimated end of season yield of said cotton crop, then monitoring said first cotton crop at key growth stages such that data can be entered to record an actual profile of said cotton crop and enable re-estimation of the end of season yield of said first cotton crop based on a combination of actual profile data and simulated profile data, and at least one of said key growth stages is First Flower of said cotton crop and said re-estimation of the end of season yield can occur with data collected at said First Flower or thereafter, and when said First Flower of said cotton crop is reached and said cotton crop data of said First Flower is entered into said crop model, the actual profile of said cotton crop as it progresses, can be benchmarked with the profile of another crop.

20. A machine implemented method as claimed in claim 19, wherein said another crop is either an earlier crop identified by a historical profile stored in said database, or a similar crop for which data is being collected for and said similar crop has also reached its First Flower and said cotton crop and said similar crop are comparatively benchmarked to each other.
